(19) United States
(12) Patent Application Publication
(10) Pub. No.: US 2020/0357704 A1
(43) Pub. Date: Nov. 12, 2020

(54) LASER TRIANGULATION SENSOR SYSTEM AND METHOD FOR WAFER INSPECTION

(71) Applicant: Onto Innovation Inc., Wilmington, MA (US)

(72) Inventor: John Schaefer, Miller Place, NY (US)

(73) Assignee: Onto Innovation Inc., Wilmington, MA (US)

(21) Appl. No.: 16/762,011

(22) PCT Filed: Nov. 6, 2018
(86) PCT No.: PCT/US2018/059404

§ 371 Date: May 6, 2020

Related U.S. Application Data
(60) Provisional application No. 62/582,290, filed on Nov. 6, 2017.

(51) Int. Cl. H01L 21/66; G01B 11/06

(52) U.S. Cl. CPC H01L 22/12; G01B 11/0675; G01B 11/0625

(57) ABSTRACT

Systems and methods for measuring a dimension of a 3D structure of a semiconductor device, such as height of a pad or bump supported by a film layer. The methods can include obtaining raw data implicating a height of the 3D structure with a laser triangulation sensor and adjusting the raw data with a compensation factor that accounts for effects of the film layer and a thickness of the film layer.

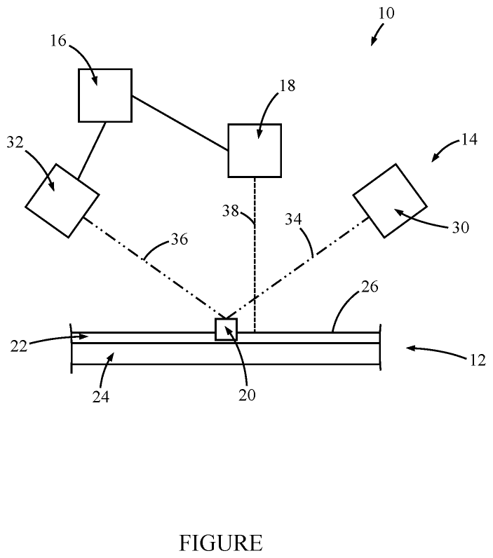

### CROSS REFERENCE TO RELATED APPLICATIONS

This application is a PCT Application that claims priority to U.S. Provisional Patent Application No. 62/582,290, filed Nov. 6, 2017, entitled “LASER TRIANGULATION CALIBRATION” and is incorporated herein by reference.

### BACKGROUND

Obtaining a useful measurement relies, in large part, on having a reliable and consistent reference. Machinists use precision ground granite or cast iron surfaces as a reference. Few such reliable references exist in the semiconductor field where measurements are made using light. Semiconductor substrates and the structures formed thereon (sometimes collectively referred to as a semiconductor wafer) are themselves work pieces and are actively being modified during a fabrication process. Accordingly, measurements on an integrated circuit (IC) device are made relative to other features. Even this can be challenging where the physics of light impose variability on the measurements themselves. While measurements using light can be and are quite accurate, variability in the materials used to form the IC device can introduce error into the measurements.

In relatively large structures provided as part of a semiconductor wafer, such as hemispherical bumps having a diameter of around 100 μm, errors due to the presence of partially transparent layers of passivation or resist surrounding and/or supporting the bump can make it difficult to measure the height of such a bump from its base to its top. Conventionally, one or more measurements of the position of the plane that defines the base position of a large hemispherical bump are made and thereafter measurements of the top of the bumps are captured and used to compute the height of the bumps. The base position is measured using any of a number of techniques. For example, an interferometer can be used to localize the base plane of the pillar bumps. Ellipsometers, chromatic confocal sensors, reflectometers, and even laser triangulation systems can be used to localize the base plane, provided that the passivation or resist are essentially transparent to the wavelength of the light being used. For relatively large structures such as hemispherical bumps, larger errors (in an absolute sense) are more permissible provided that the accuracy and repeatability are sufficient good. For smaller structures, such as pads formed on top of passivation or other layers as part of a redistribution layer (RDL) (for example), the amount of error (in an absolute sense) that is allowable is much smaller. As a result, some of the errors imposed by variability in the optical qualities of the structures of the IC device must be identified and minimized.

With some semiconductor wafer fabrication processes, a relatively low bump or pad is formed on the top of a layer of passivation or protection material (e.g., polyimide, polybenzoxazole, etc.). The low bump may be electrically connected from below by a via or laterally by a trace. These structures are well understood in the art. A bump is used to make an electrical connection either by means of mechanical contact (pressure) or by means of a solder connection. In both cases, the bump must satisfy certain physical criteria to be satisfactory. A bump that is too high may create difficulties in making connections to adjacent bumps. A bump that is too low may not make sufficient contact. As is obvious, the ideal scenario is one in which all of the bumps are the same height. Further, it is desirable for all of the bumps to have the same profile as well. The same height and profile allows for predictable connections to be made.

One means of measuring bump height and profile is a laser triangulation sensor or system. Laser triangulation involves directing a focused laser onto a surface and measuring the position of the reflected light (spot). As the angle of incidence and the angle of reflection are the same by definition, deviation of the reflected light is due to the height of the surface being measured. Using a simple sensor such as a position sensing device (PSD) or a CCD/CMOS camera, one may readily measure the height of a bump. Moving the device that is under test relative to the laser allows multiple positions of the device to be measured. Relative motion between a focused laser spot of a laser triangulation sensor and a device under test involves some combination of moving the device upon a stage, raster scanning a focused laser spot, focusing the laser to a line, and/or imposing multiple laser spots at one time.

Of import here is the fact that metals of the type used to form conductive structures of interest such as bumps, traces, etc., are good reflectors of light, whereas the non-conductive layer or materials that surround the metallic structures with many semiconductor wafer constructions (e.g., a polymer passivation or protection layer such as polyimide) are typically not. This leads to the problems described above, i.e., it can be hard to find a bottom or base reference plane or structure for use in making measurements of the bump with a laser triangulation sensor. This is particularly difficult where the structure or bump under test is relatively small. In general terms, the bump height is determined by detecting a “top” of the bump and a “bottom” of the bump. The bump bottom is conventionally designated as being relative to a surface of the supporting passivation or protection layer. The incident light used for measurement is subject to or experiences birefringence and interference at the passivation or protection layer, causing the laser triangulation sensor to “detect” something other than the surface of the passivation or protection layer (e.g., because polyimide isn't completely transparent, when the laser triangulation sensor attempts to detect the bottom of this layer, it will actually “find” it somewhere in the middle). While these effects are small in the general scheme of things, this type of variability can negatively affect the measurement of small bump height.

Interference fringes at a passivation or protection layer can lead to variation in otherwise identical measurements. The index of refraction and the thickness of the passivation layer also play a role in measurement in that interference can induce a drop in the intensity of light returned to a triangulation sensor from the surface of the IC device. The drop in intensity is caused by destructive interference induced where the passivation is some multiple of the wavelength of light used by the laser triangulation system. In one example, a 70.5 nm change in the thickness of the passivation layer was found to cause a 1.0 μm decrease in measured thickness.

### SUMMARY

Some aspects of the present disclosure are directed toward systems and method for measuring at least one dimension of a 3D structure of a semiconductor device. For example, with some methods of the present disclosure, a height of a bump, pad or other 3D structure supported by a film layer (e.g., a passivation layer, protection layer, or other polymer layer) is measure by obtaining raw height data for the 3D structure and surrounding regions using a laser triangulation sensor. The raw height data is adjusted by a compensation factor to generate an actual height of the 3D structure. The compensation factor is based upon a thickness of the film layer. In some embodiments, the compensation factor accounts for think film interference of light generated by the laser triangulation sensor at the film layer. In related embodiments, the raw height data includes intensity information and an estimated Z value for a bottom of the 3D structure; in these and similar embodiments, the step of adjusting the raw height data includes adjusting the estimated Z value for the bottom of the 3D structure based upon the intensity information. In some embodiments of the present disclosure, a measurement device, such as a measurement device including at least one of an interferometer and a reflectometer, to measure a thickness of the film layer.

### BRIEF DESCRIPTION OF THE DRAWINGS

The FIGURE is a block diagram of a system for measuring a dimension of a 3D structure in accordance with principles of the present disclosure, and illustrates methods of the present disclosure.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

Some embodiments of the present disclosure provide systems and methods for measuring a dimension (e.g., height or z dimension) of a 3D structure of a semiconductor wafer or similar device using a laser triangulation sensor. The laser triangulation sensors of the present disclosure can generally be akin to laser triangulation sensors conventionally employed for measuring 3D structures of semiconductor wafers. With the systems and methods of the present disclosure, data obtained from the laser triangulation sensor is compensated or adjusted for at least one, optionally both, of interference caused by a passivation/protection layer underlying or surrounding the 3D structure of interest and an offset in a base or floor designation of the 3D structure of interest. The compensated data is then utilized to determine or designated the actual measured dimension of the 3D structure. In some embodiments, the compensation is based upon a parameter of the passivation/protection layer, for example as measured by a device apart from the laser triangulation sensor (e.g., a device including an interferometer).

One example of a system 10 in accordance with principles of the present disclosure is shown in the FIGURE relative to a semiconductor wafer 12. The system 10 includes a laser triangulation sensor 14, a processor 16, a stage (not shown) to support the wafer 12, and an optional second measurement device 18. The system 10 is operable to perform methods of the present disclosure in evaluating or measuring one or more dimensions (e.g., height) of a 3D structure 20 carried or formed by the semiconductor wafer 12. As a point of reference, semiconductor wafer 3D structures of interest can assume various forms, such as pads, bumps, etc., and can be generated at various stages of fabrication. The systems and methods of the present disclosure can be beneficially useful in evaluating or measuring one or more dimensions of a metal 3D structure (e.g., solder, copper, etc.) that is formed in, on and/or surrounded by a non-metal layer, such as a film layer 22 illustrated in the FIGURE. As is known in the art, the film layer 22 can assume various forms (passivation layer, protection layer, resist layer, etc.) and can be formed of a transparent or semi-transparent polymer. The film layer 22 is generated on or over a base substrate 24, with at least a portion of the 3D structure 20 projecting beyond a top surface 26 of the film layer 22. One or more intermediate layers (not shown) can be formed between the base substrate 24 and the film layer 22. Further, the semiconductor wafer 12 can include one or more additional features that electrically interconnected the 3D structure 20 with other regions (e.g., a conductive via, an intermetallic compound (IMC) layer, an under bump metal (UBM) layer, etc.). Regardless, the systems and methods of the present disclosure can account for possible errors or inconsistencies in the raw data generated by the laser triangulation sensor 14 caused by the film layer 22.

The laser triangulation sensor 14 can assume any form capable of laser triangulation for wafer inspection. In general terms, the laser triangulation sensor 14 includes a projection unit 30, a detection unit 32, and a stage (not shown). The projection unit 30 is configured to generate and project a laser beam 34 having a preset spot or line size onto the surface to be examined (e.g., from a laser projection “gun” that may be mounted normal to the surface being examined). In addition to a laser source, the projection unit 30 can include various optical devices or elements (e.g., waveguide, attenuator, etc.). Further, the projection unit 30 can include a laser mount that may allow for the following adjustments: translation in Z to get the focal point on the objective lens center axis, rotation about Z to get the line parallel to the tool Y axis, rotation about X to get the line center on the objective lens center axis or to flatten the field of the laser, and rotation about Y to get the plane on the objective lens nominal working distance.

The detection unit 32 can include one or more components capable of receiving or detecting light 36 returned from the surface being examined. For example, the light detecting unit can be a camera such as a CCD or CMOS imaging chip or a position sensing device (PSD) as known in the art and arranged at an offset angle to the projection axis of the laser beam 34. The detection unit 32 can observe the position of the laser spot or line in its field of view and output a signal describing the angle at which the spot appeared in the field of view. The range to the object can be computed from the angle information when the distance between the laser projection axis and the light detection unit 32 is known. The offset angle between the laser beam and the line of sight of the light detection unit is often referred to as the “triangulation angle”. Based on which part of the detector the light reflected from the imaged object impinges, the height or “z-component” of the object at the point at which the light spot or line impinges upon the object may be determined.

In some embodiments, the laser triangulation sensor 14 can be configured such that a laser line is imaged onto a three-dimensional (3D) camera by microscope optics. The 3D camera may acquire two-dimensional (2D) images of the laser line, convert the 2D images into 3D lines in a field programmable gate array (FPGA) processing board, and output the 3D lines to a computer or the processor 16 via a universal serial bus (USB) (e.g., USB3.0) interface in some embodiments.

The processor 16 can be a computer or computer-like device, programmed or configured to receive and act upon raw data or information generated by the laser triangulation sensor 14, and in particular the detection unit 32, as described in greater detail below. In some embodiments, the processor 16 can be provided as part of, or operates to control operation of, the laser triangulation sensor 14. In other embodiments, the laser triangulation sensor 14 can include a computer, processor or other electronic device programmed or configured to control operation thereof as will be understood by one of ordinary skill. Regardless, the processor 16 operates to adjust or compensate raw data or information obtained by the detection unit 32 based upon user-provided information and/or information optionally generated by the second measurement device 18.

In general terms, the systems and methods of the present disclosure adjust or compensate for possible errors in readings generated by the laser triangulation sensor 14 due to, at least in part, light interference at the film layer 22. Interference, being related to the thickness of the film layer (e.g., passivation/resist materials) 22, can be quantified by measuring the thickness of the film or passivation layer 22. With well controlled thin film coatings, one to three measurements of the passivation/resist material layer 22 can be used to approximate the thickness of the material over the entire substrate 24. This approximation is not always correct however. For example, it has been found that spin coating processes of the type commonly used to apply passivation or resist materials to a wafer will do so in a manner that results in radially positioned rings of material having a larger thickness. Where this type of structure accrues (and its presence may in fact be useful for controlling the spin coating process), a line of thickness measurements across the radius or diameter of the substrate 24 will assist in quantifying the variation in thin film thickness of the film layer 22. Alternatively, a thickness sensor (e.g., the second measurement device 18) may precede, follow, or be co-located with operation of the laser triangulation sensor 14 to obtain the passivation/resist layer 22 thickness.

The index of refraction of the passivation/resist layer(s) 22 surrounding or underlying the 3D structure 20 (e.g., a bump or pad) is rarely known with any specificity. To be clearer, the index of refraction is generally known to engineers that have designed the IC device in question, but the process engineers tasked with monitoring the actual fabrication may not have access to this information. This is particularly so where IC devices are processed in multiple fabrication facilities. Because the index of refraction of a material will affect the position or depth at which light is reflected, the unknown index of refraction can be problematic.

This is due in part to the fact that light is returned from a passivation layer at some position that is different from what is expected. The difference is due to differing indices of refraction between substrates. The laser triangulation sensor 14 presumes a particular index of refraction for a substrate and accordingly reports data as if that index of refraction is present and the signal returned from the substrate is well correlated with an actual height. Where the index of refraction differs, the measured height will be subject to an offset. This offset can be removed or corrected by calibrating the laser triangulation sensor 14 or by obtaining an accurate index of refraction from the substrate under test. As the index of refraction of materials common to the manufacture of semiconductor devices tends to change in a linear fashion, a few measurements of actual film thickness made using the second sensor 18 such as an interferometer can be compared with raw height measurements from the laser triangulation sensor 14. Note that interferometers, while accurate and well suited for measuring bump height, are not fast enough to measure all bumps on a substrate.

In some embodiments, the systems and methods of the present disclosure adjust data obtained by the laser triangulation sensor 14 to account for a thin film interference effect with the film layer 22. In some embodiments, the systems and methods of the present disclosure adjust data obtained by the laser triangulation sensor 14 to compensate for light penetration at the film layer 22 so that a true height of the 3D structure 20 with respect to the top surface 26 of the film layer 22 can be provided. In yet other embodiments, the systems and methods of the present disclosure compensate for both the thin film interference effect and for film penetration.

It has surprisingly been discovered that with operation of a laser triangulation sensor, small changes in thickness of the film layer 22 across the wafer 12 cause the interference to shift between constructive and destructive, which in turn causes an apparent shift in the centroid Z position obtained the laser triangulation sensor 14. It has further been surprisingly discovered that since Z appears to decrease proportionally to intensity, it is possible to compensate for this thin film interference effect by adjusting an obtained Z value based on intensity of light received at the detection unit 32. Intensity variation is caused by interference between laser reflection from the top surface 26 and the bottom surface of the film or passivation layer 22. An intensity fringe will occur for each small change in thickness of the film layer 22 (e.g., a fringe will occur in 405 nm wavelength laser light applied to a film with a refractive index of 1.6 for every 141 nm change in film thickness). With this in mind, some systems and methods of the present disclosure adjust or compensate a Z value obtained by the laser triangulation sensor 14 (e.g., a Z value implicating a floor or bottom of the 3D structure 20) based upon the determined intensity of the collected light, for example to adjust an obtained Z value to match the Z value corresponding to an intensity fringe peak. In some embodiments, the compensated Z can be determined as:

Z_{compensated}=Z+(I_{fringe}−I_{measured})*C_{factor}, where: (1)
Z=measured Z value,
I_{fringe}=fringe intensity,
I_{measured}=measured intensity for a particular pixel, and
C_{factor}=compensation factor based upon film layer thickness.

In some embodiments, for example, intensity is in reference to gray scale imaging, with the intensity values expressed in terms of a grayscale number (e.g., I_{fringe} can be 190 grayscale (gs)). The compensation factor C_{factor} can be designated or determined as a function of expected error or change in the measured Z due change in the thickness of the film layer 22. In some embodiments, C_{factor} can be a value that accounts for the thickness of the film layer 22 (e.g., C_{factor}=0.0066 μm/gs). In other embodiments, C_{factor} can be a value that is further modified by an actual or expected thickness of the film layer 22 corresponding to the particular pixel location under review. In yet other embodiments, the thin film interference compensation algorithm can be designated as:

Z_{compensated}=Z+(Iₚₑₐₖ−I_{measured})/(Iₚₑₐₖ−I_{valley})*t*C_{factor}, where: (2)
Iₚₑₐₖ=fringe peak intensity (intensity above which no compensation is applied),
I_{valley}=fringe valley intensity (intensity below which max compensation is applied),
t=thickness of the film layer 22.

The film layer thickness t can be an estimated nominal thickness. The film layer thickness t can alternatively be designated or determined for the particular pixel location under review as described below.

In some embodiments, the Z value determined from the raw information or data generated by the laser triangulation sensor 14 is adjusted to indicate a height (Z value) of the 3D structure 20 relative to the top surface 26 of the film layer 22. With this approach, and where multiple ones of the 3D structures 20 are being evaluated and compared to one other, designating the height or Z relative to the top surface 26 of the film layer 22 can be desired or meaningful. Operation of the laser triangulation sensor 14 can, in some embodiments, consistently locate or measure the top surface 26 as incorrectly existing somewhere within the thickness of the film layer 22, returning a height value for the 3D structure 20 being measured that is too high. In some embodiments, the systems and methods of the present disclosure apply an offset or penetration factor to the 3D structure 20 Z value generated by the laser triangulation sensor 14 that accounts for this phenomenon. In some embodiments, the penetration factor is a function of, or is modified by, a thickness of the film layer 22. For example, in some embodiments, the second measurement device 18 can be operated to measure 3D structure height and/or thickness of the film layer 22 at various locations across the wafer 12, and then calculate an appropriate penetration factor or offset to Z value measurements of the 3D structure 20 as generated by the laser triangulation sensor 14. For example, the penetration factor or offset can be a percentage of a thickness of the film layer 22. In one non-limiting example, the laser triangulation sensor 14 and the second measurement device 18 can each be operated to determine a height of at least one 3D structure; the so-determined heights are then compared to one another and related to a thickness of the film layer 22 (an estimated thickness or a measured thickness) in designating a penetration factor or offset for future Z value measurements by the laser triangulation sensor 14 (e.g., the laser triangulation sensor 14 may be found to measure a height or Z value for a 3D structure of interest on the order of 0.7 μm greater than the measurement generated by the second measurement device 18; where the film layer 22 at the location of the has an expected or measured thickness of 2.2 μm, a penetration factor or offset of 32% can be determined (0.7 μm/2.2 μm). With subsequent operation of the laser triangulation sensor 14 in measuring the height or Z value of one or more 3D structures, the height or Z value returned by the laser triangulation sensor 14 is reduced by 32% of the thickness of the film layer 22 at the location of the 3D structure being analyzed.

As alluded to above, some non-limiting systems and methods of the present disclosure account or compensate for both thin film interference and for film penetration in Z value raw data generated by the laser triangulation sensor 14. In some embodiments, the compensated Z can be determined as:

Z_{compensated}=Z+(Iₚₑₐₖ−I_{measured})/(Iₚₑₐₖ−I_{valley})*t*C_{factor}t*P_{factor,} where: (3)
Iₚₑₐₖ=fringe peak intensity (intensity above which no compensation is applied),
I_{valley}=fringe valley intensity (intensity below which max compensation is applied),
C_{factor}=thin film interference factor as described above,
P_{factor}=penetration factor as described above, and
t=thickness of the film layer 22 at the wafer location of the obtained Z value.

The film layer thickness t can be an estimated nominal thickness. The film layer thickness t can alternatively be designated or determined for the particular wafer location under review as described below.

With one or more of the systems and methods of the present disclosure, a thickness of the film layer 22 can be utilized. In some embodiments, the thickness of the film layer 22 can be designated or entered by a user. In some embodiments, the film layer 22 can be treated by the systems and methods of the present disclosure as having a constant or uniform thickness across the wafer 12, with this nominal thickness value being designated by a user or measured.

In other embodiments, the thickness t of the film layer 22 at the location of the particular 3D structure 20 being measured can be determined or approximated based upon an expected or measured thickness of the film layer 22 at the center of the wafer 12. As a point of reference, it has surprisingly been found that with some commonly employed film layer compositions and applications, a thickness of the film layer 22 will decrease from the center of the wafer 12 to the edge of the wafer 12, and that this radial distance-based decrease in thickness can be approximated by an equation. For example, the film layer thickness t at any location along the wafer 12 and used an any of the above compensation equations can be determined as:

t=T_{centerNorm}*(a*r2+b*r+c), where: (4)
T_{centerNorm}=nominal thickness of the film layer at a center of the wafer (user entered or measured),
r=radial distance from wafer center to location of the 3D structure being measured,
a, b, and c=user configurable polynomial coefficients with appropriate defaults that can be determined by fitting a polynomial to one or more film thickness profiles obtained with a measurement device, such as the second measurement device 18.

In other embodiments, the actual thickness of the film layer 22 at a center of the wafer 12 can be measured by the second measurement device 18 (represented, for example, by line 38 in the FIGURE). The so-measured actual thickness can then be employed with any of the equations above.

In other embodiments, the actual thickness of the film layer 22 at various radial locations (relative to center) along the wafer 12 can be measured (e.g., by the second measurement device 18) and stored in a look up table. In related embodiments, the actual thickness measurements can be used to generate a radial location thickness profile that is stored in a look up table. Regardless, during subsequent operation of the laser triangulation sensor 14 in measuring a height of the 3D structure 20, a radial location of the 3D structure of interest relative to a center of the wafer 12 will be known and can be compared to the stored look up table to obtain a corresponding film layer thickness for use in the compensation equation. With these and other embodiments, the second measurement device 18 can be a device incorporating one or both of interferometry and reflectometry. In one non-limiting embodiment, for example, the second measurement device 18 can be or include a visible thickness and shape sensor (VTSS) incorporated into a defect inspection tool available under the trade designation NSX® 330 Series from Rudolph Technologies of Wilmington, Mass. As a point of reference, while an interferometer-based measurement device can accurately measure the thickness of the film layer 22 (as well as other features, such as 3D structures), it has a slower operational time or scanning rate (and thus lower throughput) as compared to the laser triangulation sensor 14. In some embodiments, the interferometer-based measurement device can be operated to obtain actual film layer thickness at various radial locations (from which a radial thickness profile can be generated, for example) by taking film layer thickness measurements at the center of the wafer 12 and in only one radial direction from the center (as opposed to taking measurements across an entire dimeter of the wafer 12). It has surprisingly been found that with some conventional film layer constructions (e.g., a conventional passivation layer), the film layer 22 has near perfect radial uniformity, facilitating meaningful film layer thickness information for an entirety of the wafer with measurements taken in only one radial direction from the center. Further, a sample spacing between film layer thickness measurements can be not less than 10 μm, optionally on the order of 200 μm. It has surprisingly been found that where the interferometer-based measurement device is operated to obtain film layer thickness measurements in only one radial direction from the center of the wafer 12 at a sample spacing of 200 μm, a useful film layer thickness profile can be generated at a scan time of less than 4 seconds. Other instruments and techniques can alternatively be employed to obtain actual film layer thickness information in other embodiments.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1-9. (canceled)

10. A method of measuring a height of a 3D structure supported by a film layer of a semiconductor device, the method comprising:
obtaining raw height data for the 3D structure and surrounding regions using a laser triangulation sensor; and
adjusting the raw height data by a compensation factor to generate an actual height of the 3D structure, wherein the compensation factor is based upon a thickness of the film layer.

11. The method of claim 10, wherein the compensation factor accounts for thin film interference of light generated by the laser triangulation system at the film layer.

12. The method of claim 11, wherein the raw height data includes intensity information and an estimated Z value for a bottom of the 3D structure, and further wherein the step of adjusting includes adjusting the estimated Z value for the bottom of the 3D structure based upon the intensity information.

13. The method of claim 10, wherein the compensation factor accounts for penetration of light from the laser triangulation sensor at the film layer in designating a bottom of the 3D structure at a top surface of the film layer.

14. The method of claim 10, wherein the compensation factor accounts for thin film interference of light generated by the laser triangulation system at the film layer and for penetration of light from the laser triangulation sensor at the film layer in designating a bottom of the 3D structure at a top surface of the film layer.

15. The method of claim 10, wherein the compensation factor is based upon a user-entered nominal thickness of the film layer.

16. The method of claim 10, wherein the compensation factor is based upon the thickness of the film layer at a location of the 3D structure.

17. The method of claim 16, wherein the thickness of the film layer at the location of the 3D structure is computed from a user-entered nominal thickness of the film layer at a center of the semiconductor device.

18. The method of claim 16, wherein the thickness of the film layer at the location of the 3D structure is computed from an actual thickness of the film layer at a center of the semiconductor device as measured by a measurement device comprising at least one of an interferometer and a reflectometer.

19. The method of claim 16, wherein the thickness of the film layer at the location of the 3D structure is derived from a lookup table correlating film layer thickness with radial location, the method further comprising:
operating a measurement device to obtain thickness values of the film layer at a plurality of radial locations along the semiconductor device, the measurement device comprising at least one of an interferometer and a reflectometer; and
generating the lookup table from the obtained thickness values.

20. The method of claim 19, wherein the step of adjusting further includes comparing a location of the 3D structure relative to the center of the semiconductor device with the lookup table.

21. The method of claim 10, wherein the step of adjusting further includes adjusting the raw height data based upon a determined intensity of light collected by the laser triangulation sensor.

22. The method of claim 21, wherein the step of adjusting further includes:
determining an intensity fringe peak in the light collected by the laser triangulation sensor; and
adjusting the raw height data based upon a difference between the intensity fringe peak and a measured intensity for a particular pixel of the raw height data.

23. A system for measuring a height of a 3D structure supported by a film layer of a semiconductor device, the system comprising:
a laser triangulation sensor projection unit configured to project a laser beam onto the semiconductor device;
a laser triangulation detection unit configured to detect light of the projected laser beam reflected from the semiconductor device; and
a processor electronically linked to the laser triangulation detection unit;
wherein the processor is programmed to:
obtain raw height data for the 3D structure and surrounding regions from the laser triangulation detection unit, and
adjust the raw height data by a compensation factor to generate an actual height of the 3D structure, wherein the compensation factor is based upon a thickness of the film layer.

24. The system of claim 23, wherein the compensation factor accounts for thin film interference of light generated by the laser triangulation system at the film layer.

25. The system of claim 24, wherein the raw height data includes intensity information and an estimated Z value for a bottom of the 3D structure, and wherein the processor is further programmed to adjust the estimated Z value for the bottom of the 3D structure based upon the intensity information.

26. The system of claim 23, wherein the compensation factor is based upon the thickness of the film layer at a location of the 3D structure.

27. The system of claim 26, wherein the processor is further programmed to compute the thickness of the film layer at the location of the 3D structure from a user-entered nominal thickness of the film layer at a center of the semiconductor device.

28. The system of claim 26, wherein the processor is programmed to store a lookup table correlating film layer thickness with radial location.

29. The system of claim 23, wherein the laser triangulation sensor projection unit is configured to project the laser beam as having one of a preset spot size and a preset line size.
